(19) United States
(12) Patent Application Publication
(10) Pub. No.: US 2005/0133785 A1
(43) Pub. Date: Jun. 23, 2005

(54) Device and method for detecting the overheating of a semiconductor device

(75) Inventors: Georg Eggers, Munchen (DE); Norbert Wirth, Unterschleissheim (DE); Herbert Benzinger, Munchen (DE); Thomas Huber, Munchen (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munich (DE)

(21) Appl. No.: 10/995,529

(22) Filed: Nov. 24, 2004

(30) Foreign Application Priority Data
Nov. 27, 2003 (DE) 103 55 333.9

(51) Int. Cl. H01L 23/58; G01R 31/26

(52) U.S. Cl. 257/48; 438/14

(57) ABSTRACT

The invention relates to a method and a device (1, 11, 21) for detecting the overheating of a semiconductor device, comprising a temperature measuring means (3, 13, 23) that changes its electrical conductivity when the temperature of the semiconductor device changes.

### CLAIM FOR PRIORITY

This application claims the benefit of priority to German Application No. 103 55 333.9, which was filed in the German language on Nov. 27, 2003, the contents of which are hereby incorporated by reference.

The invention relates to a device and a method for detecting the overheating of a semiconductor device.

Semiconductor devices, e.g. appropriate, integrated (analog or digital) computing circuits, semiconductor memory devices such as functional memory devices (PLAs, PALs, etc.) and table memory devices (e.g. ROMs or RAMs, in particular SRAMs and DRAMs, e.g. SDRAMs), etc. are subject to comprehensive tests in the course of their manufacturing process as well as subsequent to their manufacturing.

For instance, even before all the desired processing steps have been performed on the wafer (i.e. already in a semifinished state of the semiconductor devices), the (semifinished) devices (that are still being on the wafer) may, at one or a plurality of testing stations, be subject to appropriate testing methods (e.g. so-called kerf measurements at the wafer scrib frame) by means of one or a plurality of testing apparatuses.

After the finishing of the semiconductor devices (i.e. after performing all the wafer processing steps), the semiconductor devices may be subject to further testing methods at one or a plurality of (further) testing stations—for instance, the finished devices—that are still being on the wafer—may, by means of appropriate (further) testing apparatuses, be tested appropriately (“wafer tests”).

After the sawing (or scribing, and breaking, respectively) of the wafer, the devices that are then available as individual devices and are loaded into so-called carriers may be subject to appropriate further testing methods at one or a plurality of (further) testing stations.

Correspondingly, one or a plurality of further tests may (at corresponding further testing stations, and by using corresponding, further testing apparatuses) be performed e.g. after the installation of the semiconductor devices in the corresponding semiconductor device housings, and/or e.g. after the installation of the semiconductor device housing (along with the respectively incorporated semiconductor devices) in appropriate electronic modules (so-called module tests), etc.

Semiconductor devices, e.g. SDRAMs, react sensitively to strong heating.

By being heated beyond particular threshold temperatures, a semiconductor device may be damaged irreversibly or may be destroyed, respectively.

Such damages may e.g. occur in the course of the semiconductor device manufacturing process, but, for instance, also after the manufacturing only, e.g. during the soldering of the corresponding device, or during operation.

It is in particular partial damages that can not or only with relatively high effort be detected by means of the above-mentioned testing methods.

It is an object of the invention to provide a novel device and a novel method for detecting the overheating of a semiconductor device.

This and further objects are achieved by the subject matters of claims 1 and 20.

Advantageous further developments of the invention are indicated in the subclaims.

In accordance with a basic idea of the invention, a device for detecting the overheating of a semiconductor device is provided, said device comprising a temperature measuring means changing its electric conductivity when the temperature of the semiconductor device changes.

Advantageously, the temperature measuring means is designed such that the change in the electric conductivity of the temperature measuring means occurring when the temperature of the semiconductor device changes is irreversible.

Thus, it is relatively easy to determine whether there is the risk that a semiconductor device was—temporarily—overheated and might thus have been damaged irreversibly or destroyed, respectively.

In the following, the invention will be explained by means of several embodiments and the enclosed drawing. The drawing shows:

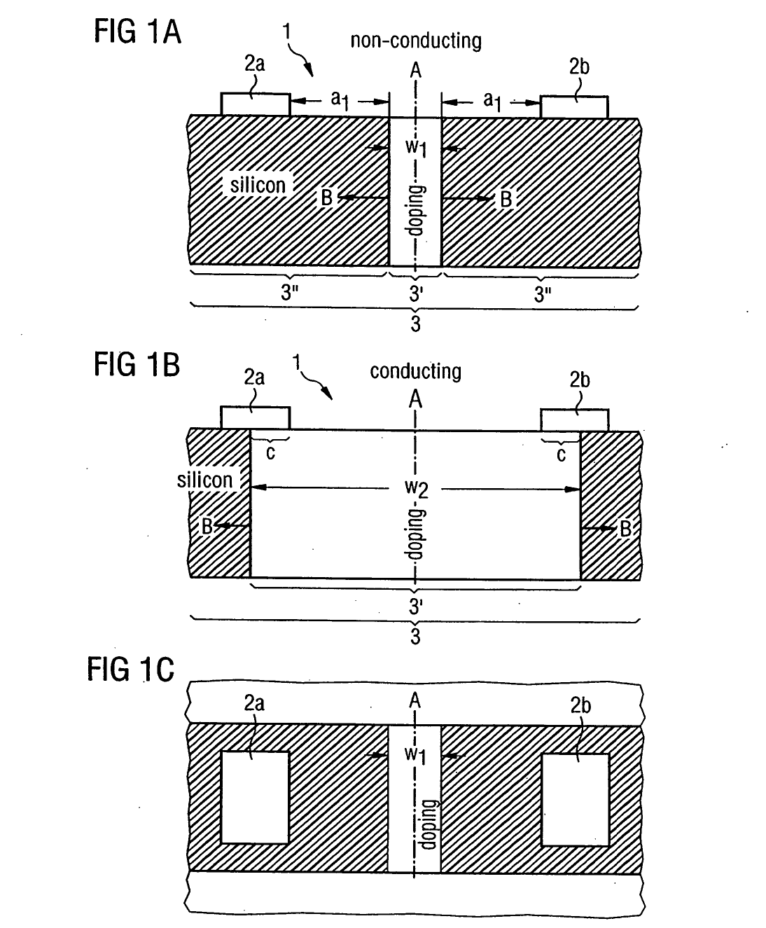

FIG. 1a a schematic representation of a device provided with a semiconductor device for detecting the overheating of the semiconductor device, in accordance with a first embodiment of the invention, in a state before the semiconductor device has been subject to relatively high temperatures;

FIG. 1b a schematic representation of the device illustrated in FIG. 1a, in a state after the semiconductor device has been subject to relatively high temperatures;

FIG. 1c a top view of the device illustrated in FIGS. 1a and 1b, in the state illustrated in FIG. 1a before the semiconductor device has been subject to relatively high temperatures;

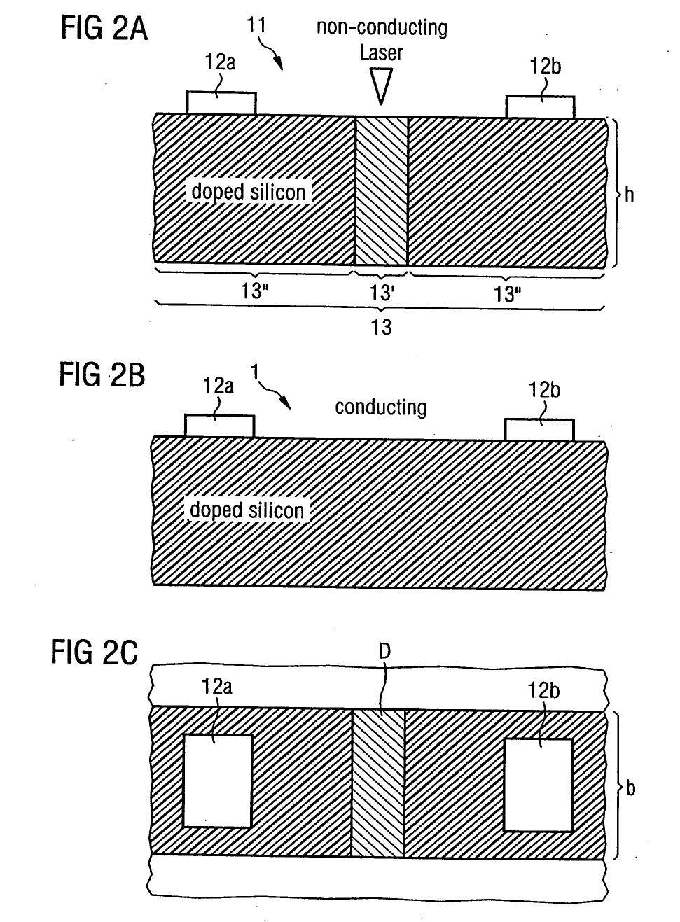

FIG. 2a a schematic representation of a device provided with a semiconductor device for detecting the overheating of the semiconductor device, in accordance with a second embodiment of the invention, in a state before the semiconductor device has been subject to relatively high temperatures;

FIG. 2b a schematic representation of the device illustrated in FIG. 2a, in a state after the semiconductor device has been subject to relatively high temperatures;

FIG. 2c a top view of the device illustrated in FIGS. 2a and 2b, in the state illustrated in FIG. 2a before the semiconductor device has been subject to relatively high temperatures;

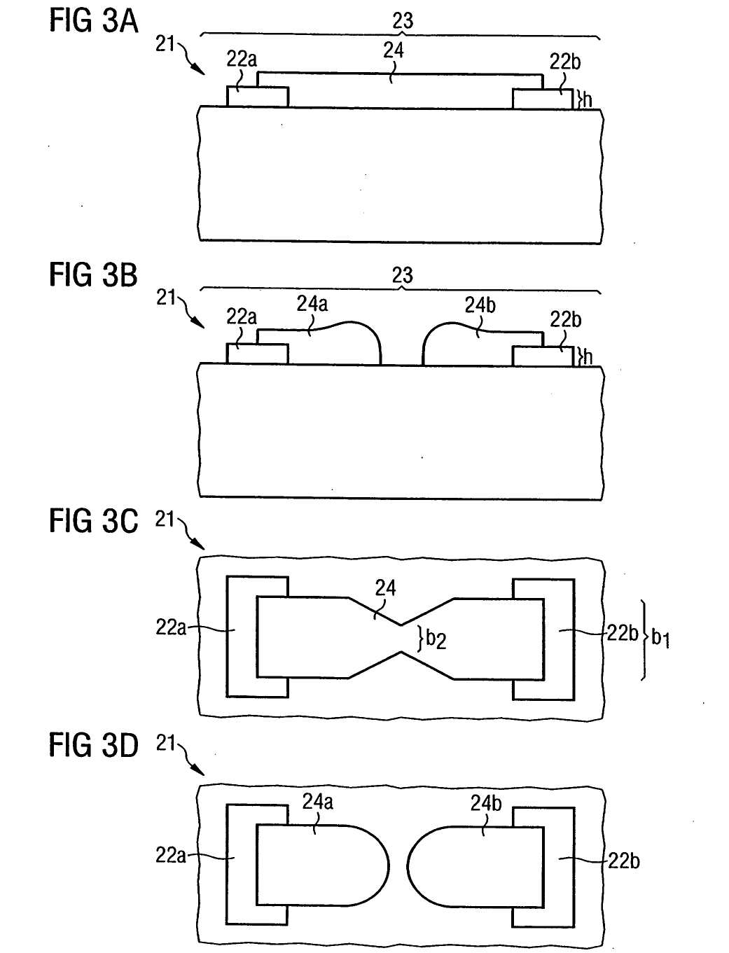

FIG. 3a a sectional view of a device provided with a semiconductor device for detecting the overheating of the semiconductor device, in accordance with a third embodiment of the invention, in a state before the semiconductor device has been subject to relatively high temperatures;

FIG. 3b a sectional view of the device illustrated in FIG. 3a, in a state after the semiconductor device has been subject to relatively high temperatures;

FIG. 3c a top view of the device illustrated in FIGS. 3a and 3b, in the state illustrated in FIG. 3a before the semiconductor device has been subject to relatively high temperatures; and

FIG. 3d a top view of the device illustrated in FIGS. 3a and 3b, in the state illustrated in FIG. 3b after the semiconductor device has been subject to relatively high temperatures.

FIG. 1a shows a schematic, lateral sectional view of a device 1 provided with a semiconductor device for detecting the overheating of the semiconductor device, in accordance with a first embodiment of the invention, in a state before the semiconductor device has been subject to relatively high temperatures.

The overheating detection device 1 may, for instance, be arranged directly at the surface of a corresponding semiconductor device, or e.g. in the interior of the semiconductor device.

The semiconductor device may, for instance, be an appropriate, integrated (analog or digital) computing circuit, or e.g. a semiconductor memory device such as a functional memory device (PLA, PAL, etc.), or a table memory device (e.g. a ROM or a RAM, in particular a SRAM or a DRAM, e.g. a SDRAM), and/or a combined computing circuit/memory device, etc.

In accordance with FIG. 1a, the overheating detection device 1 comprises two contact elements 2a, 2b, with a corresponding measuring section 3 positioned therebetween.

As is illustrated in FIG. 1c, the cross-section of the contact elements 2a, 2b may (viewed from the top) e.g. be rectangular, or e.g. also circular, oval, etc.

Again referring to FIG. 1a, the measuring section 3—positioned in a region below and between the contact elements 2a, 2b—is manufactured of an appropriate semiconductor material, e.g. silicon (e.g. of a correspondingly similar or identical basic material as the remaining portion of the semiconductor device).

A partial region 3′ of the measuring section 3—positioned substantially in the middle between the contact elements 2a, 2b—is (relatively strongly) doped, e.g. relatively strongly n-doped or relatively strongly p-doped, i.e. is of relatively good conductivity.

As compared to this, the two partial regions 3″ of the measuring section—positioned directly below the contact elements 2a, 2b, or adjacent to or contacting, respectively, the contact elements 2a, 2b—are undoped (or, alternatively: only weakly n- or p-doped), i.e. are of no or only poor conductivity.

With the doped partial region 3′, doping may be largest at or near an imagined plane A passing perpendicularly through the partial region 3′ (i.e. at a central region), and may continue decreasing with the increasing lateral distance from this imagined plane A.

The doped partial region 3′ may, for instance, be generated by a doping being injected locally into the—initially undoped—region 3 (e.g. by means of conventional diffusion methods, (ion) implantation methods, etc.).

As results from FIG. 1a and FIG. 1c, the width w₁ of the doped partial region 3′ is—initially—so small that—laterally—a certain distance a₁ exists between the lateral edge regions of the partial region 3′ and the contact elements 2a, 2b (initial state).

Thus, the—conductive—partial region 3′ is in the initial state (due to the respective non-conductive partial region 3″ positioned, in accordance with FIG. 1a and FIG. 1c, between the partial region 3′ and the respective contact element 2a, 2b) separated electrically from the contact elements 2a, 2b.

When the semiconductor device is heated, the outer limit or the respective lateral edge region, respectively, of the doped partial region 3′ is shifted—due to corresponding diffusion of the doping atoms contained in the partial region 3′—laterally in the direction of the contact elements 2a, 2b (as is illustrated in FIG. 1a by the arrows B).

As is illustrated in FIG. 1b, the dimensions of the partial region 3′, the doping intensity, the dimensions of the contact elements 2a, 2b, etc. are appropriately chosen such that, when the temperature of the semiconductor device exceeds a predetermined threshold temperature T (wherein the heating e.g. has to prevail for a certain, relatively short period t only, e.g. t<5 sec, or e.g. t<1 sec, or t<0.5 sec), the outer limit or the respective lateral edge region, respectively, of the doped partial region 3′ is shifted laterally to such an extent that the partial region 3′ gets—at least partially (here e.g.: at a region C)—into contact with the lower limiting region of the respective contact element 2a, 2b.

Thus—after the overheating of the semiconductor device (exceeding of the threshold temperature T)—the contact element 2a, the partial region 3′, and the contact element 2b are—irreversibly—electrically connected with one another (2^{nd} state).

The above-mentioned threshold temperature T is chosen such that from this temperature onwards there would be the risk of the semiconductor device being damaged irreversibly or destroyed, respectively.

The first and second contact elements 2a, 2b may, for instance, be connected directly by means of appropriate bonding wires, or e.g. indirectly by means of corresponding lines provides in or at the semiconductor device, to corresponding pins of the device housing accommodating the semiconductor device.

The first pin—that is connected with the first contact element 2a—may e.g. be connected to a first terminal of a test device, and the second pin—that is connected with the second contact element 2b—may e.g. be connected to a second test device terminal.

By applying an appropriate voltage between the first and the second test device terminals (and thus between the first and the second contact elements 2a, 2b), and subsequently measuring whether a corresponding current then flows between the contact elements 2a, 2b or not (or whether the intensity of the current flowing exceeds a predetermined threshold value), there may be determined whether no electrical connection exists between the contact elements 2a, 2b (initial state, FIG. 1a, “test passed”), or whether the contact elements 2a, 2b—as explained above—are electrically connected with one another after the overheating of the semiconductor device (2^{nd} state, FIG. 1b, “test not passed”), this indicating that the semiconductor device might have been damaged or destroyed due to overheating.

FIG. 2a shows a schematic, lateral sectional view of a device 11 provided with a semiconductor device for detecting the overheating of the semiconductor device, in accordance with a second embodiment of the invention, in a state before the semiconductor device has been subject to relatively high temperatures.

The overheating detection device 11 may, for instance, be arranged directly at the surface of a corresponding semiconductor device, or e.g. in the interior of the semiconductor device.

The semiconductor device may e.g. be an appropriate, integrated (analog or digital) computing circuit, or e.g. a semiconductor memory device such as a functional memory device (PLA, PAL, etc.), or a table memory device (e.g. a ROM or a RAM, in particular a SRAM or a DRAM, e.g. a SDRAM), and/or a combined computing circuit/memory device, etc.

The overheating detection device 11 comprises, in accordance with FIG. 2a, two contact elements 12a, 12b with a corresponding measuring section 13 positioned therebetween.

The contact elements 12a, 12b may e.g. (correspondingly similar as with the embodiment illustrated in FIGS. 1a, 1b, in particular correspondingly similar as illustrated in FIG. 1c) have (viewed from the top) e.g. a rectangular, or e.g. a circular, oval, etc. cross-section.

As is illustrated in FIG. 2a, the measuring section 13—positioned in a region below and between the contact elements 12a, 12b—is manufactured of an appropriate semiconductor material, e.g. silicon (e.g. of a correspondingly similar or identical basic material as the remaining portion of the semiconductor device).

During the manufacturing of the overheating detection device 11, the entire region of the measuring section 13 positioned below and between the contact elements 12a, 12b (e.g. the entire measuring section region) is first of all, e.g. by means of conventional diffusion methods, (ion) implantation methods, etc., relatively strongly doped, e.g. relatively strongly n-doped or relatively strongly p-doped, so that the entire measuring section region (or the entire measuring section 13, respectively) is then of—relatively good—conductivity.

Subsequently, a partial region 13′ of the measuring section—positioned substantially in the middle between the contact elements 12a, 12b—is, by means of appropriate, conventional method technologies, treated such that the above-mentioned semiconductor material changes from an initially non-amorphous, crystalline state to an amorphous state.

This may e.g. be effected by the partial region 13′ (e.g. —as illustrated in FIG. 2c—its upper limit region D) is—for a short period—irradiated from the top with a laser beam provided by a laser, and is thus heated very quickly very strongly, and subsequently cooled again very quickly very strongly.

The two partial regions 13′ of the measuring section 13—positioned directly below the contact elements 12a, 12 or adjacent to or contacting the contact elements 12a, 12, respectively—remain in the above-mentioned crystalline, i.e. conductive, state.

Since—as is illustrated in FIGS. 2a and 2c—the amorphous, and thus non-conductive partial region 13′ extends over the entire breadth b and the entire height h of the measuring section 13—that is surrounded by non-conductive material—the crystalline, conductive partial region 13″ positioned, in the drawing according to FIG. 2a, at the left and contacting the contact element 12a is—by the non-conductive partial region 13′ positioned between the conductive partial regions 13″ electrically separated from the crystalline, conductive partial region 13″ positioned in the drawing at the right and contacting the contact element 12b.

Thus—with the initial state of the overheating detection device 11 illustrated in FIGS. 2a and 2c—the contact element 12a is electrically separated from the contact element 12b by the non-conductive partial region 13′ positioned, in accordance with FIGS. 2a and 2c, between the conductive partial regions 13″.

If the semiconductor device is heated beyond a predetermined threshold temperature T (wherein the heating e.g. has to prevail for a certain, relatively short period t only, e.g. t<5 sec, or e.g. t<1 sec, or t<0.5 sec), the amorphous structures prevailing in the partial region 13′ again change to corresponding crystalline structures, this rendering the partial region 13′ electroconductive (again).

Thus—after the overheating of the semiconductor device (exceeding of the threshold temperature T)—the contact element 12a and the contact element 12b are—irreversibly—electrically connected with one another (2^{nd} state).

By an appropriate choice of the (semiconductor) materials, the dimensions of the partial region 13′, the duration and/or the intensity of the laser treatment, etc., the above-mentioned threshold temperature T may be modified or adjusted, respectively (on the exceeding of which the partial region 13′ becomes electroconductive (again) (or—for the test method explained in detail further below—becomes correspondingly conductive to such an extent that the test provides a result “not passed”).

The threshold temperature T may advantageously be chosen such that, from this temperature onwards, there would be the risk of the semiconductor device being irreversibly damaged or destroyed, respectively.

The first and second contact elements 12a, 12b may e.g. be connected directly by means of appropriate bonding wires, or e.g. indirectly by means of appropriate lines provided in or at the semiconductor device, to corresponding pins of the device housing accommodating the semiconductor device.

The first pin—that is connected with the first contact element 12a—may e.g. be connected to a first terminal of a test device, and the second pin—that is connected with the second contact element 12b—may e.g. be connected to a second test device terminal.

By applying an appropriate voltage between the first and the second test device terminals (and thus between the first and the second contact elements 12a, 12b), and subsequently measuring whether a corresponding current then flows between the contact elements 12a, 12b or not (or whether the intensity of the current flowing exceeds a predetermined threshold value), there may be determined whether no electrical connection exists between the contact elements 12a, 12b (initial state, FIG. 2a, “test passed”), or whether the contact elements 12a, 12b—as explained above—are electrically connected with one another after the overheating of the semiconductor device (2^{nd} state, FIG. 2b, “test not passed”), this indicating that the semiconductor device might have been damaged or destroyed due to overheating.

FIG. 3a shows a schematic, lateral sectional view of a device 21 provided with a semiconductor device for detecting the overheating of the semiconductor device, in accordance with a third embodiment of the invention, in a state before the semiconductor device has been subject to relatively high temperatures.

The overheating detection device 21—in particular two contact elements 22a, 22b provided with this device, and a metal layer, in particular a softmetal layer 24 (of relatively good conductivity) positioned therebetween—may e.g. be arranged directly at the surface of the corresponding semiconductor device, or e.g. on a special substrate, or e.g. in the interior of the semiconductor device. The overheating detection device 21 is surrounded by non-conductive material, e.g.—undoped—silicon (e.g. a correspondingly similar or identical—undoped—basic material as with the remaining portion of the semiconductor device).

The semiconductor device may, for instance, be an appropriate, integrated (analog or digital) computing circuit, or e.g. a semiconductor memory device such as a functional memory device (PLA, PAL, etc.), or a table memory device (e.g. a ROM or a RAM, in particular a SRAM or a DRAM, e.g. a SDRAM), and/or a combined computing circuit/memory device, etc.

In the overheating detection device 21—as is, for instance, illustrated in FIG. 3a—a corresponding measuring section 23 is formed by the two contact elements 12a, 12b, and the metal layer 24 positioned therebetween.

As is illustrated in FIG. 3c, the contact elements 22a, 22b may (viewed from the top) e.g. be of rectangular, or e.g. also circular, oval, etc. cross-section.

Again referring to FIG. 3a, a region of the metal layer 24—positioned at the left in the drawing—contacts the contact element 22a, and a region of the metal layer 24—positioned at the right in the drawing—contacts the contact element 22b, with the metal layer 24 extending, in the present embodiment, with a substantially constant height h between the two contact elements 22a, 22b.

As is illustrated in FIG. 3c, the metal layer 24 has a—relatively large—breadth b1 in the area of or close to the contact elements 22a, 22b, respectively.

In a region positioned roughly in the middle between the contact elements 22a, 22b, the metal layer 24 is—relatively strongly—tapered, so that there the metal layer 24 has only a—relatively small—breadth b2 that may only amount to less than the half, e.g. less than a third, or less than a fourth, of the breadth b1 of the metal layer 24 at or close to the contact elements 22a, 22b.

As results from FIG. 3a and FIG. 3c, the (left) contact element 22a is (due to the above-explained design of the metal layer 24) connected electroconductively with the (right) contact element 22b via the metal layer 24 (initial state).

As is illustrated in FIGS. 3b and 3c, the dimensions of the metal layer 24, the dimensions of the contact elements 22a, 22b, and—in particular—the material forming the metal layer (metal or metal alloy, etc.) are appropriately chosen such that, when the temperature of the semiconductor device exceeds a predetermined threshold temperature T (wherein the heating has to prevail for a certain, relatively short period t only, e.g. t<5 sec, or e.g. t<1 sec, or t<0.5 sec), the metal layer 24 is “melted apart”.

The above-mentioned threshold temperature T is chosen such that, from this temperature onwards, there would be the risk of the semiconductor device being damaged irreversibly or destroyed, respectively.

For adjusting the threshold temperature T, the material, in particular metal/alloy used for constructing the metal layer 24, in particular may be chosen such that the melting point of the material is approximately identical to the above-mentioned threshold temperature T.

After the melting apart of the metal layer 24—at the above-mentioned tapered region having merely the breadth b2—two separate metal layer parts 24a, 24b—that are separated from each other electrically (by the air therebetween)—have, in accordance with FIGS. 3a and 3d, been generated from the original, one-piece metal layer 24.

Thus—after the overheating of the semiconductor device (exceeding of the threshold temperature T)—the contact element 22a and the contact element 22b are—irreversibly—separated from one another electrically (2^{nd} state).

By the above-described design of the metal layer 24 it is prevented that—after the metal layer 24 has been melted apart—the two single metal layer parts 24a, 24b that have been generated may combine with one another again (later).

This becomes possible in particular by the metal structure—here chosen by way of example and explained in detail above—with which the metal or alloy material, respectively, of the metal layer 24 is, in the melted-apart state, contracted—due to correspondingly acting capillary forces—to form the above-mentioned metal layer parts 24a, 24b at the two contact elements 22a, 22b.

This effect can also be supported, for instance, by an appropriate choice of the material and/or the property of the substrate positioned directly below the metal layer 24 (and possibly being selected specifically), in particular by taking into account the wetting characteristics of the material used for the metal layer 24 on the substrate.

The first and second contact elements 22a, 22b may, for instance, be connected directly by means of appropriate bonding wires, or e.g. indirectly by means of appropriate lines provided in or at the semiconductor device, to corresponding pins of the device housing accommodating the semiconductor device.

The first pin—connected with the first contact element 22a—may e.g. be connected to a first terminal of a test device, and the second pin—connected with the second contact element 22b—may e.g. be connected to a second test device terminal.

By applying an appropriate voltage between the first and the second test device terminals (and thus between the first and the second contact elements 22a, 22b), and subsequently measuring whether a corresponding current then flows between the contact elements 22a, 22b or not, there may be determined whether an electrical connection exists—via the metal layer 24—between the contact elements 22a, 22b (initial state, FIG. 3a, “test passed”), or whether the contact elements 22a, 22b—as explained above—are electrically separated from one another after the overheating of the semiconductor device and the melting apart of the metal layer 24 effected thereby (2^{nd} state, FIG. 3b, “test not passed”), this indicating that the semiconductor device might have been damaged or destroyed due to overheating.

Instead of every single one of the above-described overheating detection devices 1, 11, 21, a plurality of—e.g. two, three, or more—overheating detection devices 1, 11, 21 (e.g. each constructed correspondingly similar as described above) may also be arranged on the same semiconductor device (each e.g. becoming electroconductive or non-conductive with the same or substantially the same threshold temperature T, or e.g. each with—possibly relatively strongly—different threshold temperatures T1, T2, T3, T4, etc. (so that—depending on the number of the different threshold temperatures T1, T2, T3, T4 used—the temperature range (T1-T2, T2-T3, etc.) including that temperature to which the semiconductor device was maximally subjected may be determined for the semiconductor device)).

List of Reference Signs

1 overheating detection device
2a contact element
2b contact element
3 measuring section
3′ doped measuring section partial region
3″ undoped measuring section partial region
3″ undoped measuring section partial region
11 overheating detection device
12a contact element
12b contact element
13 measuring section
13′ amorphous measuring section partial region
13″ crystalline measuring section partial region
13″ crystalline measuring section partial region
21 overheating detection device
22a contact element
22b contact element
23 measuring section
24 soft metal layer

1. A device (1, 11, 21) for detecting the overheating of a semiconductor device, comprising a temperature measuring means (3, 13, 23) which changes its electrical conductivity when the temperature of the semiconductor device changes.

2. The device (1, 11) according to claim 1, wherein said temperature measuring means (3, 13) increases its electrical conductivity on increasing of the temperature, in particular becomes conductive, in particular strongly conductive, on exceeding of a predetermined threshold or category temperature (T).

3. The device (1, 11) according to claim 2, wherein said temperature measuring means (3, 13) is non-conductive, in particular strongly non-conductive, prior to the exceeding of the threshold temperature (T).

4. The device (1, 11) according to claim 1, wherein said temperature measuring means (3, 13) comprises a region (3′, 3″, 13′, 13″) consisting of a semiconductor material.

5. The device (1) according to claim 4, wherein said semiconductor material region (3′, 3″) comprises an undoped or weakly doped partial region (3″), and a more strongly doped partial region (3′).

6. The device (1) according to claim 5, comprising at least one contact element (2a) which—initially—only contacts the undoped or weakly doped partial region (3″) of said semiconductor material region (3′, 3″), not, however, the more strongly doped partial region (3′).

7. The device (1) according to claim 6, wherein said contact element (2a) and said semiconductor material regions (3′, 3″) are designed and arranged such that on increasing of the temperature, in particular on exceeding of the threshold temperature (T), the more strongly doped partial region (3′) spreads—by diffusion—to such an extent into the undoped or weakly doped partial region (3″) that it contacts the contact element (2a).

8. The device (11) according to claim 4, wherein said semiconductor material region (13′, 13″) comprises an amorphous partial region (13′).

9. The device (1) according to claim 8, wherein said semiconductor material region (13′, 13″) additionally comprises a crystalline partial region (13″).

10. The device (1) according to claim 9, comprising at least one contact element (12a) contacting said crystalline partial region (13″) of said semiconductor material region (13′, 13″).

11. The device (1) according to claim 8, wherein said amorphous partial region (13″) is designed and constructed such that it becomes crystalline on increasing of the temperature, in particular on exceeding of the threshold temperature (T).

12. The device (21) according to claim 1, wherein said temperature measuring means (23) decreases its electrical conductivity on increasing of the temperature, in particular becomes non-conductive, in particular strongly non-conductive, on exceeding of a predetermined threshold temperature (T).

13. The device (21) according to claim 12, wherein said temperature measuring means (23) is conductive, in particular strongly conductive, prior to the exceeding of the threshold temperature (T).

14. The device (21) according to claim 12, wherein said temperature measuring means (23) comprises a metal layer (24).

15. The device (21) according to claim 14, wherein said metal layer (24) comprises one or more recesses, or a tapering.

16. The device (21) according to claim 15, additionally comprising two contact elements (22a, 22b) being in contact with said metal layer (24), and wherein said recess or recesses, or said tapering, is positioned between said contact elements (22a, 22b).

17. The device (21) according to claim 14, wherein said metal layer (24) is a softmetal layer.

18. The device (1, 11, 21) according to claim 14, wherein said temperature measuring means (3, 13, 23) is arranged directly on the semiconductor device.

19. The device (1, 11, 21) according to claim 14, wherein the change in the electrical conductivity of said temperature measuring means (3, 13, 23) occurring on the change in the temperature of the semiconductor device is irreversible.

20. A method for detecting the overheating of a semiconductor device, using a temperature measuring means (3, 13, 23) that changes its electrical conductivity when the temperature of the semiconductor device changes, said method comprising the step of: detecting the conductivity of said temperature measuring means (3, 13, 23) for detecting of whether the semiconductor device has been overheated.
